(19) United States
(12) Patent Application Publication
(10) Pub. No.: US 2008/0036538 A1
(43) Pub. Date: Feb. 14, 2008

(54) RAIL-TO-RAIL CLASS AB AMPLIFIER

(76) Inventor: Myung-Jin Lee, Hwaseong-si (KR)

Correspondence Address: F. CHAU & ASSOCIATES, LLC, 130 WOODBURY ROAD, WOODBURY, NY, 11797, US

(21) Appl. No.: 11/776,209

(22) Filed: Jul. 11, 2007

(30) Foreign Application Priority Data
Aug. 9, 2006 (KR) 2006-75291

(51) Int. Cl. H03F 3/30

(52) U.S. Cl. 330/255; 330/261

(57) ABSTRACT

A rail-to-rail class AB amplifier includes an input circuit for converting a voltage difference between a first input signal and a second input signal into respective currents, a first current adder circuit for adding a drain current of a first input NMOS transistor and a drain current of a second input NMOS transistor, a second current adder circuit for adding a drain current of a first input PMOS transistor and a drain current of a second input PMOS transistor, a floating current source for controlling a bias current of the first current adder circuit and the second current adder circuit, a control circuit for controlling a voltage level of the drain terminal of a second cascode PMOS transistor and a second cascode NMOS transistor, and an output circuit coupled to the drain terminals of the second cascode PMOS transistor and the second NMOS transistor.

### CROSS-REFERENCE TO RELATED APPLICATION

This application claims priority under 35 USC § 119 to Korean Patent Application No. 2006-75291, filed on Aug. 9, 2006 in the Korean Intellectual Property Office (KIPO), the disclosure of which is incorporated herein in its entirety by reference.

### BACKGROUND OF THE INVENTION

1. Technical Field

The present disclosure relates to an operational amplifier and, more particularly, to a rail-to-rail class AB amplifier.

2. Discussion of Related Art

An amplifier amplifies a signal received from a converter or input source, and then outputs the amplified signal to an output device or another amplifying stage. When the input signal level is very low, the input signal is generally required to be sufficiently amplified for operating the output device. Generally, a push-pull amplifier circuit implemented with CMOS transistors is widely used. Amplifier circuits widely used for audio amplifiers are classified into two types: an analog amplifier circuit and a digital amplifier circuit.

A class A amplifier, a class B amplifier and a class AB amplifier are kinds of analog amplifiers. A class D amplifier is a kind of digital amplifier. For audio applications, the analog amplifiers are more widely used than the digital amplifiers, because the high linearity of the analog amplifiers is more important than the high efficiency of the digital amplifiers.

Recently, a class A amplifier, a class B amplifier and a class AB amplifier having high linearity have been used for the audio amplifier. Nevertheless, a power loss may be increased when those analog amplifiers are implemented as high-power output amplifiers.

That is, the analog amplifier has high linearity but poor efficiency. A representative analog amplifier having those characteristic is the class A amplifier. The class A amplifier has a power toss larger than a maximum output, thus, an efficiency of the class A amplifier is not higher than about 20 percent.

To obviate this problem, a push-pull class B amplifier is used by coupling two transistors as an emitter follower in order to reduce power loss. The push-pull class B amplifier, however, generates crossover distortion even if it has relatively high efficiency.

In addition, the two transistors in the class B amplifier are alternatively turned on/off. When a small current flows through the transistors, the on/off state may be promptly switched. When a large current flows through the transistors, however, it is difficult to switch the on/off state promptly. Therefore, the large current flowing through the transistors may cause noise, such as total harmonic distortion, due to the difficulty of obtaining a prompt switching operation.

A class AB amplifier having both characteristics of a class A amplifier and a class B amplifier has some amount of current flowing through the transistors. The amount of the flowing current is smatter than an amount of a current flowing in the class A amplifier and larger than an amount of a current flowing in the class B amplifier.

Therefore, as the bias current is increased, characteristics of the class AB amplifier becomes similar to characteristics of the class A amplifier. On the other hand, the smaller bias current causes characteristics of the class AB amplifier to be more similar to characteristics of the class B amplifier.

U.S. Pat. No. 5,311,145 discloses a floating current source that provides a bias current for class AB output. Supply voltage dependency is mostly compensated by the floating current source, because the floating current source and a bias circuit in the AB amplifier have the same structure. As a level of a semiconductor process shrinks, however, it is very difficult to obtain a sufficient gain due to poor impedance characteristics of each transistor in the amplifier. More specifically, when the amplifier operates as a buffer, an error may occur in a high resolution system.

U.S. Pat. No. 6,150,883 discloses an amplifier using a gain boosting circuit so that output impedance may be amplified by using a boosting circuit to obtain a high gain. A total gain is, however, difficult to be controlled because a cascode configuration uses a current flowing through each branch of additional amplifiers. That is, a total gain is difficult to be controlled since the amplifier adopting a cascode configuration does not have additional current sources.

### SUMMARY OF THE INVENTION

Accordingly, exemplary embodiments of the present invention are provided to substantially obviate one or more problems due to limitations and disadvantages of the related art.

Exemplary embodiments of the present invention provide a rail-to-rail class AB amplifier capable of effectually controlling a total gain and enhancing output impedance.

In exemplary embodiments of the present invention, a rail-to-rail class AB amplifier includes an input circuit, a first current adder circuit, a second current adder circuit, a floating current source, a control circuit and an output circuit. The input circuit includes a first input PMOS transistor, a second input PMOS transistor, a first input NMOS transistor, and a second input NMOS transistor. Each of the first input PMOS transistor, the second input PMOS transistor, the first input NMOS transistor, and the second input NMOS transistor is configured as a folded cascode circuit. The input circuit converts a voltage difference between a first input signal and a second input signal into respective currents. The first current adder circuit includes a first cascode PMOS transistor, a second cascode PMOS transistor, a first level shifter coupled to a source terminal of the second cascode PMOS transistor, and a first boosting amplifier. The first boosting amplifier receives a first bias voltage and an output of the first level shifter. The first boosting amplifier outputs a boosted output signal to a gate terminal of the second cascode PMOS transistor. The first cascode PMOS transistor has a source terminal coupled to a drain terminal of the first input NMOS transistor. The second cascode PMOS transistor has a source terminal coupled to a drain terminal of the second input NMOS transistor. The first current adder circuit adds a drain current of the first input NMOS transistor and a drain current of the second input NMOS transistor. The first current adder circuit outputs the added current to a drain terminal of the second cascode PMOS transistor. The second current adder circuit includes a first cascode NMOS transistor, a second cascode NMOS transistor, a second level shifter coupled to a source terminal of the second cascode NMOS transistor, and a second boosting amplifier. The second boosting amplifier receives a second bias voltage and an output of the second level shifter. The second boosting amplifier outputs a boosted output signal to a gate terminal of the second cascode NMOS transistor. The first cascode NMOS transistor has a source terminal coupled to a drain terminal of the first input PMOS transistor. The second cascode NMOS transistor has a source terminal coupled to a drain terminal of the second input PMOS transistor. The first current adder circuit adds a drain current of the first input PMOS transistor and a drain current of the second input PMOS transistor. The first current adder circuit outputs the added current to a drain terminal of the second cascode NMOS transistor. The floating current source is coupled between a drain terminal of the first cascode PMOS transistor and a drain of the first cascode NMOS transistor. The floating current source controls a bias current of the first current adder circuit and the second current adder circuit. The control circuit is coupled between the drain terminal of the second cascode PMOS transistor and a drain of the second cascode NMOS transistor. The control circuit controls a voltage level of the drain terminal of the second cascode PMOS transistor and a voltage level of the second cascode NMOS transistor. The output circuit is coupled to the drain terminal of the second cascode PMOS transistor and the drain terminal of the second NMOS transistor.

The input circuit may further include a first current source and a second current source. The first current source may be coupled to a power voltage. The first current source may provide a current to the first input NMOS transistor and the second input NMOS transistor. The second current source may be coupled to a ground voltage. The second current source may provide a current to the first input PMOS transistor and the second input PMOS transistor.

The first current adder circuit may further include a first PMOS transistor and a second PMOS transistor. The first PMOS transistor may have a source terminal coupled to a power voltage, a gate terminal coupled to the drain terminal of the first cascode PMOS transistor, and a drain terminal coupled to the drain terminal of the first input NMOS transistor. The second PMOS transistor may have a source terminal coupled to the power voltage, a gate terminal coupled to the gate terminal of the first PMOS transistor, and a drain terminal coupled to the drain terminal of the second input NMOS transistor. The first level shifter may include a third PMOS transistor and a first current source. The third PMOS transistor may have a source terminal coupled to the source terminal of the second cascade PMOS transistor. The third PMOS transistor may be diode-connected. The first current source may be coupled between a ground voltage and the third PMOS transistor. The first current source may provide a current to the third PMOS transistor. The first boosting amplifier may include a first boosting transistor, a second boosting transistor, a third boosting transistor, a fourth boosting transistor and a fifth boosting transistor. The first boosting transistor may provide a constant current. The first boosting transistor may have a source terminal coupled to the power voltage, and a gate terminal coupled to the gate terminal of the first PMOS transistor. The second boosting transistor may have a source terminal coupled to a drain terminal of the first boosting transistor, and a gate terminal for receiving the first bias voltage. The third boosting transistor may have a source terminal coupled to the drain terminal of the first boosting transistor, and a gate terminal coupled to a drain terminal of the third PMOS transistor. The fourth boosting transistor may be coupled between the second boosting transistor and the ground voltage. The fourth boosting transistor may be diode-connected. The fifth boosting transistor may have a drain terminal coupled to a drain terminal of the third boosting transistor, a gate terminal coupled to the fourth boosting transistor, and a source terminal coupled to the ground voltage. Each of the first, the second, and the third boosting transistor may correspond to a PMOS transistor. Each of the fourth and the fifth boosting transistors may correspond to an NMOS transistor.

The second current adder circuit may further include a first NMOS transistor and a second NMOS transistor. The first NMOS transistor may have a source terminal coupled to a ground voltage, a gate terminal coupled to the drain terminal of the first cascode NMOS transistor, and a drain terminal coupled to the drain terminal of the first input PMOS transistor. The second NMOS transistor may have a source terminal coupled to the ground voltage, a gate terminal coupled to the gate terminal of the first NMOS transistor, and a drain terminal coupled to the drain terminal of the second input PMOS transistor. The second level shifter may include a third NMOS transistor and a second current source. The third NMOS transistor may have a source terminal coupled to the source terminal of the second cascode NMOS transistor, the third NMOS transistor being diode-connected. The second current source may be coupled between a power voltage and the third NMOS transistor. The second current source may provide a current to the third NMOS transistor. The second boosting amplifier may include a first boosting transistor, a second boosting transistor, a third boosting transistor, a fourth boosting transistor and a fifth boosting transistor. The first boosting transistor may provide a constant current. The first boosting transistor may have a source terminal coupled to the ground voltage, and a gate terminal coupled to the gate terminal of the first NMOS transistor. The second boosting transistor may have a source terminal coupled to a drain terminal of the first boosting transistor, and a gate terminal for receiving the second bias voltage. The third boosting transistor may have a source terminal coupled to the drain terminal of the first boosting transistor, and a gate terminal coupled to a drain terminal of the third NMOS transistor. The fourth boosting transistor may be coupled between the second boosting transistor and the power voltage. The fourth boosting transistor may be diode-connected. The fifth boosting transistor may have a drain terminal coupled to a drain terminal of the third boosting transistor, a gate terminal coupled to the fourth boosting transistor, and a source terminal coupled to the power voltage. Each of the first, the second, and the third boosting transistors may correspond to an NMOS transistor. Each of the fourth and the fifth boosting transistors may correspond to a PMOS transistor.

The output circuit may include a first output transistor and a second output transistor. The first output transistor may have a source terminal coupled to a power terminal, a gate terminal coupled to the drain terminal of the second cascode PMOS transistor, and a drain terminal coupled to an output terminal. The second output transistor may have a drain terminal coupled to the output terminal, a gate terminal coupled to the drain terminal of the second cascode NMOS transistor, and a source terminal coupled to a ground voltage. The first output transistor may correspond to a PMOS transistor. The second output transistor may correspond to an NMOS transistor. The output circuit may further include a first capacitor and a second capacitor. The first capacitor may be coupled between the drain terminal of the second cascode PMOS transistor and the output terminal. The second capacitor may be coupled between the drain terminal of the second cascode NMOS transistor and the output terminal. The output circuit may further include a first branch and a second branch. The first branch may include a first current source and a first diode serially coupled to the first current source between the power voltage and the ground voltage. The second branch may include a second current source and a second diode serially coupled to the second current source between the power voltage and the ground voltage. The first diode may correspond to a diode-connected NMOS transistor. The second diode may correspond to a diode-connected PMOS transistor.

The floating current source may include a first floating transistor and a second floating transistor. The first floating transistor may be coupled between the drain terminal of the first cascode PMOS transistor and the drain terminal of the first cascode NMOS transistor. The first floating transistor may have a gate terminal for receiving a voltage of a coupling point between the first current source and the first diode. The second floating transistor may be coupled between the drain terminal of the first cascode PMOS transistor and the drain terminal of the first cascode NMOS transistor. The second floating transistor may have a gate terminal for receiving a voltage of a coupling point between the second current source and the second diode. The first floating transistor may correspond to a PMOS transistor. The second floating transistor may correspond to an NMOS transistor.

The control circuit may include a first control transistor and a second control transistor. The first control transistor may be coupled between the drain terminal of the second cascode PMOS transistor and the drain terminal of the second cascode NMOS transistor. The first control transistor may have a gate terminal for receiving a voltage of a coupling point between the first current source and the first diode. The second control transistor may be coupled between the drain terminal of the second cascode PMOS transistor and the drain terminal of the second cascode NMOS transistor. The second control transistor may have a gate terminal for receiving a voltage of a coupling point between the second current source and the second diode. The first control transistor may correspond to a PMOS transistor. The second control transistor may correspond to an NMOS transistor.

### BRIEF DESCRIPTION OF THE DRAWINGS

Exemplary embodiments of the present invention will be understood in more detail from the following descriptions taken in conjunction with the accompanying drawings.

FIG. 1 is a block diagram illustrating a rail-to-rail class AB amplifier according to an exemplary embodiment of the present invention.

FIG. 2 is a circuit diagram illustrating a rail-to-rail class AB amplifier according to an exemplary embodiment of the present invention.

FIG. 3 is a circuit diagram illustrating a rail-to-rail class AB amplifier according to exemplary embodiment of the present invention.

### DESCRIPTION OF EXEMPLARY EMBODIMENTS

Exemplary embodiments of the present invention will now be described more fully with reference to the accompanying drawings, in which exemplary embodiments of the present invention are shown. The present invention may, however, be embodied in many different forms and should not be construed as limited to the exemplary embodiments set forth herein. Rather, these exemplary embodiments are provided so that this disclosure will be thorough and complete, and will fully convey the scope of the invention to those of ordinary skill in the art. Like reference numerals refer to like elements throughout this application.

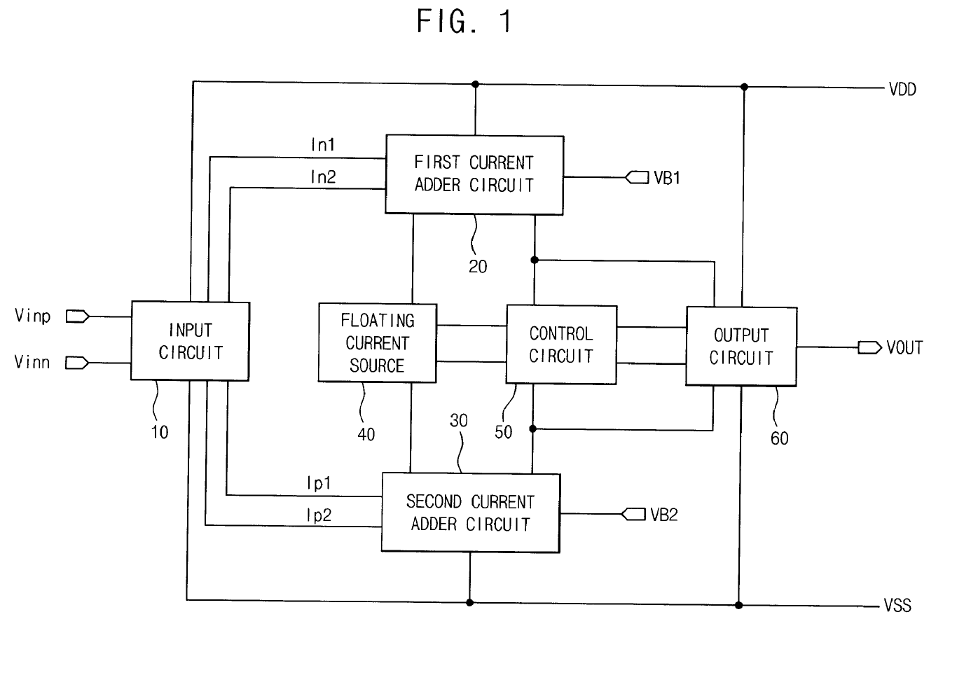

FIG. 1 is a block diagram illustrating a rail-to-rail class AB amplifier according to an exemplary embodiment of the present invention.

Referring to FIG. 1, the rail-to-rail class AB amplifier includes an input circuit 10, a first adder circuit 20, a second adder circuit 30, a floating current source 40, a control circuit 50, and an output circuit 60.

The input circuit 10 is coupled between a power supply voltage VDD and a ground voltage VSS. The input circuit 10 may convert a voltage difference between a first input signal Vinp and a second input signal Vinn into a current.

The first current adder circuit 20 is coupled to the power supply voltage VDD, the floating current source 40, and the control circuit 50. The first current adder circuit 20 may receive a first current In1 and a second current In2 and add the first current In1 and the second current In2. The first current adder circuit 20 may be biased by a first bias voltage VB1 that is externally provided.

The second current adder circuit 30 is coupled among the floating current source 40, the control circuit 50, and a ground voltage VSS. The second current adder circuit 40 may receive a third current Ip1 and a fourth current Ip2, and add the third current Ip1 and the fourth current Ip2. The second current adder circuit 40 may be biased by a second bias voltage VB2 that is externally provided.

The floating current source 40 is coupled between the first current adder circuit 20 and the second current adder circuit 30. The floating current source 40 may control a bias current for the first and second current adder circuits 20 and 30.

The control circuit 50 is coupled between the first current adder circuit 20 and the second current adder circuit 30. The control circuit 50 may control voltage levels of the first and second current adder circuits 20 and 30.

The output circuit 60 is coupled between the power supply voltage VDD and the ground voltage VSS. The output circuit 60 may be coupled to output stages of the first current adder circuit 20 and the second current adder circuit 30 and may be controlled by the control circuit 50.

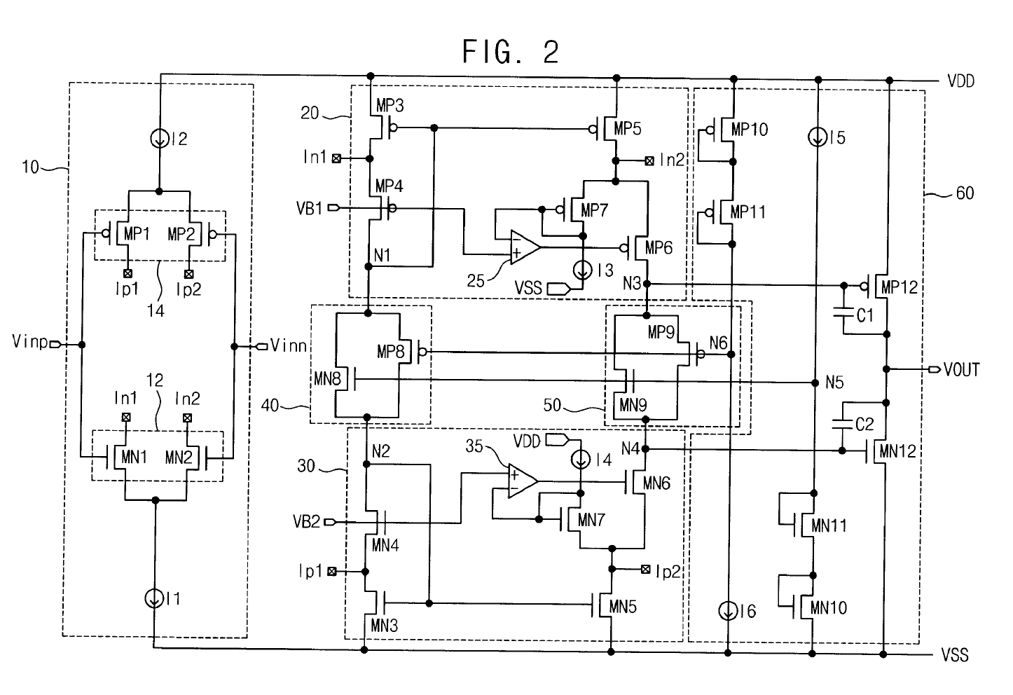

FIG. 2 is a circuit diagram illustrating a rail-to-rail class AB amplifier according to an exemplary embodiment of the present invention.

Referring to FIG. 2, the rail-to-rail class AB amplifier may include the input circuit 10, the first current adder circuit 20, the second current adder circuit 30, the floating current source 40, the control circuit 50, and the output circuit 60.

The input circuit 10 may include a first current source I1, a first differential amplifier circuit 12, a second differential amplifier 14, and a second current source I2.

The first differential amplifier circuit 12 may include a first input NMOS transistor MN1 and a second input NMOS transistor MN2. The second differential amplifier 14 may include a first input PMOS transistor MP1 and a second input PMOS transistor MP2. The first and second differential amplifier circuits 12 and 14 may form a rail-to-rail input stage, and may receive a full swing input voltage having a range that is nearly a voltage difference between the ground voltage VSS and the power supply voltage VDD.

The first current source I1 is coupled to the ground voltage VSS and may provide a constant current to the first differential amplifier circuit 12.

The first current source I1 is coupled between the first differential amplifier circuit 12 and the ground voltage VSS. The first differential amplifier circuit 12 converts a voltage difference between the first input signal Vinp and the second input signal Vinn into a current, and outputs the converted current to a first differential output terminal In1 and a second differential output terminal In2.

The second current source I2 is coupled to the power supply voltage VDD, and may provide a constant current to the second differential amplifier circuit 14.

The second current source I2 is coupled between the second differential amplifier circuit 14 and the power supply voltage VDD. The second differential amplifier circuit 14 converts a voltage difference between the first input signal Vinp and the second input signal Vinn into a current, and outputs the converted current to a third differential output terminal Ip1 and a fourth differential output terminal Ip2.

The input circuit 10 enables the operational amplifier to perform a rail-to-rail operation. That is, an input common mode voltage range of the input circuit 10 may be the entire range between a plus power supply voltage rail and a minus power supply voltage rail.

The first current adder circuit 20 may be coupled to the power supply voltage VDD, and the second adder circuit 30 may be coupled to the ground voltage VSS.

The first current adder circuit 20 is coupled to the first output terminal In1 and the second output terminal In2 of the first differential amplifier circuit 12, and the first current adder circuit 20 adds the currents provided from the first differential amplifier 12.

The first current adder circuit 20 may include a first PMOS transistor MP3, a second PMOS transistor MP5, a third PMOS transistor MP7, a first cascode PMOS transistor MP4, a second PMOS transistor MP6, a first boosting amplifier 25, and a third current source I3.

The first PMOS transistor MP3 and the first cascode PMOS transistor MP4 are serially connected between the power supply voltage VDD and a first node N1. A source terminal of the first PMOS transistor MP3 is coupled to the power supply voltage VDD. A gate terminal of the first PMOS transistor MP3 is coupled to the first node N1. A drain terminal of the first PMOS transistor MP3 is coupled to the first differential output terminal In1. A source terminal of the first cascode PMOS transistor MP4 is coupled to the first differential output terminal In1. A gate terminal of the first cascode PMOS transistor MP4 receives a first bias voltage VB1. A drain terminal of the first cascode PMOS transistor MP4 is coupled to the first node N1.

A source terminal of the second PMOS transistor MP5 is coupled to the power supply voltage VDD. A drain terminal of the second PMOS transistor MP5 is coupled to the second differential output terminal In2. A gate terminal of the first PMOS transistor MP3 is coupled to the gate terminal of the first PMOS transistor MP3 and the first node N1.

A source terminal of the second cascode PMOS transistor MP6 is coupled to the second differential output terminal In2. A gate terminal of the second cascode PMOS transistor MP6 is coupled to an output stage of the first boosting amplifier 25. A drain terminal of the second cascode PMOS transistor MP6 is coupled to a third node N3.

The third PMOS transistor MP7 is diode-connected. A source terminal of the third PMOS transistor MP7 is coupled to the source terminal of the second cascode PMOS transistor MP6. A drain terminal of the third PMOS transistor MP7 is coupled to a third current source I3.

A plus input terminal of the first boosting amplifier 25 receives the first bias voltage VB1, and a minus input terminal of the first boosting amplifier 25 is coupled to the gate terminal of the third PMOS transistor MP7.

The third current source I3 is coupled to the ground voltage VSS, and the third current source I3 may provide a constant current to the third PMOS transistor MP7. The third PMOS transistor MP7 and the third current source may form a first level shifter.

The second current adder circuit 30 is coupled to the third output terminal Ip1 and the fourth output terminal Ip2 of the second differential amplifier circuit 14, and the second current adder circuit 30 adds the currents provided from the second differential amplifier 14.

The second current adder circuit 30 may include a first cascode NMOS transistor MN4, a second NMOS transistor MN6, a first NMOS transistor MN3, a second NMOS transistor MN5, a third NMOS transistor MN7, a second boosting amplifier 35, and a fourth current source I4.

The first NMOS transistor MN3 and the first cascode NMOS transistor MN4 are serially connected between the ground voltage VSS and a second node N2. A source terminal of the first NMOS transistor MN3 is coupled to the ground voltage VSS. A gate terminal of the first NMOS transistor MN3 is coupled to the second node N2. A drain terminal of the first NMOS transistor MN3 is coupled to the third differential output terminal Ip1. A source terminal of the first cascode NMOS transistor MN4 is coupled to the third differential output terminal Ip1. A gate terminal of the first cascode NMOS transistor MN4 receives a second bias voltage VB2. A drain terminal of the first cascode NMOS transistor MN4 is coupled to the second node N2.

A source terminal of the second NMOS transistor MN5 is coupled to the ground voltage VSS. A drain terminal of the second NMOS transistor MN5 is coupled to the fourth differential output terminal Ip2. A gate terminal of the first NMOS transistor MN3 is coupled to the gate terminal of the first NMOS transistor MN3 and the second node N2.

A source terminal of the second cascode NMOS transistor MN6 is coupled to the fourth differential output terminal Ip2. A gate terminal of the second cascode NMOS transistor MN6 is coupled to an output stage of the second boosting amplifier 35. A drain terminal of the second cascode NMOS transistor MN6 is coupled to a fourth node N4.

The third NMOS transistor MN7 is diode-connected. A source terminal of the third NMOS transistor MN7 is coupled to the fourth differential output terminal Ip2. A drain terminal of the third NMOS transistor MN7 is coupled to the fourth current source I4.

A plus input terminal of the second boosting amplifier 35 receives the second bias voltage VB2. A minus input terminal of the second boosting amplifier 35 is coupled to the gate of the third NMOS transistor MN7.

The fourth current source I4 is coupled to the power supply voltage VDD, and the fourth current source I4 may provide a constant current to the third NMOS transistor MN7.

A current adder circuit in a conventional rail-to-rail class AB amplifier includes a current mirror comprising four transistors of same size, and adds output currents provided by an input circuit.

In this exemplary embodiment two separate transistors, the second cascode PMOS transistor MPG and the third PMOS transistor MP7, in the first current adder circuit 20 in FIG. 2, however, contribute to reducing a chip size. The third PMOS transistor MP7 may operate as a level shifter, thereby performing gain boosting with the first boosting amplifier 25.

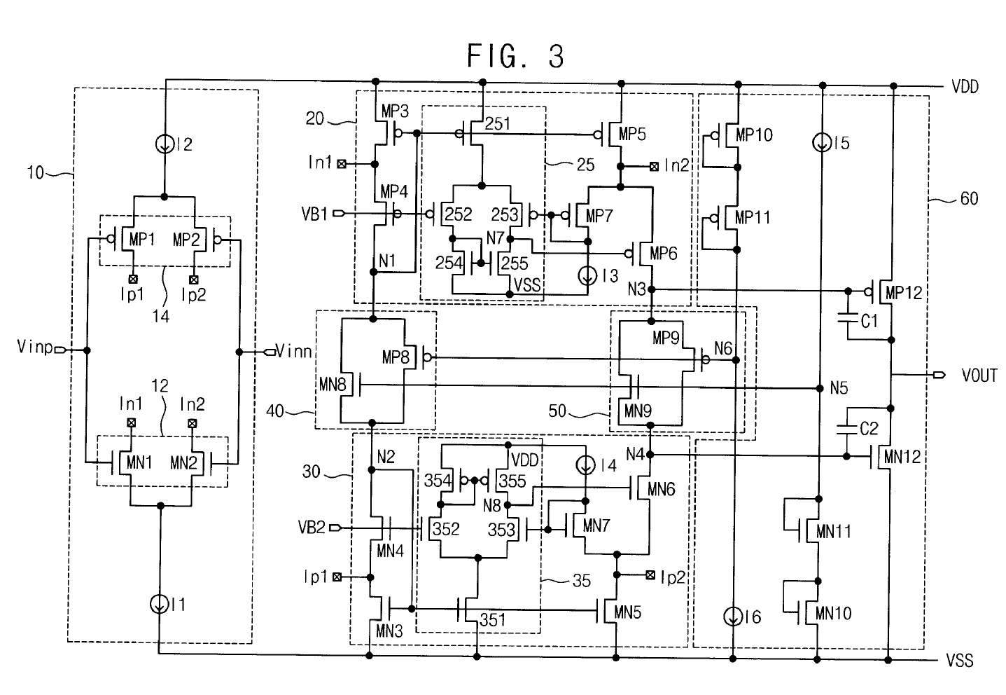

Similarly, two separate transistors, the second cascode NMOS transistor MN6 and the third NMOS transistor MN7, implemented in the second current adder circuit 30 in FIG. 2 contribute to reducing a chip size. The third NMOS transistor MN7 may operate as a level shifter, thereby performing gain boosting with the second boosting amplifier 35. Related operations will be described hereinbelow with reference to FIG. 3.

The floating current source 40 is coupled between the first node N1 and the second node N2. The floating current source 40 may include a floating PMOS transistor MP8 and a floating NMOS transistor MN8.

The control circuit 50 is coupled between the third node N3 and the fourth node N4. The control circuit 50 may include a control PMOS transistor MP9 and a control NMOS transistor MN9.

The output circuit 60 may include a fifth current source I5, a sixth current source I6, a first output transistor MP12, a second output transistor MN12, a fourth NMOS transistor MN10, a fifth NMOS transistor MN11, a fourth PMOS transistor MP10, a fifth PMOS transistor MP11, a first capacitor C1, and a second capacitor C2.

The fifth current source I5 is coupled to the power supply voltage VDD, and provides a current to the fourth NMOS transistor MN10 and fifth NMOS transistor MN11. Each of the fourth NMOS transistor MN10 and fifth NMOS transistor MN11 is diode-connected. The fourth NMOS transistor MN10 and fifth NMOS transistor MN11 are coupled to each other serially between the fifth current source I5 and the ground voltage VSS. A voltage of 2 Vgs is provided to the fifth node N5 by the fourth NMOS transistor MN10 and fifth NMOS transistor MN11. Herein, 2 Vgs indicates a voltage difference between a gate terminal and a source terminal. The voltage of the fifth node N5 corresponding to 2 Vgs is provided to a gate terminal of the floating NMOS transistor MN8 and a gate terminal of the control NMOS transistor MN9.

The sixth current source I6 is coupled to the ground voltage VSS, and provides a current to the fourth PMOS transistor MP10 and fifth PMOS transistor MP11. Each of the fourth PMOS transistor MP10 and fifth PMOS transistor MP11 is diode-connected. The fourth PMOS transistor MP10 and fifth PMOS transistor MP11 are coupled to each other serially between the sixth current source I6 and the power supply voltage VDD. A voltage of VDD-2 Vgs is provided to the sixth node N6 by the fourth PMOS transistor MP10 and fifth PMOS transistor MP11. Herein, VDD-2 Vgs indicates a voltage difference between a gate terminal and a source terminal. The voltage of the sixth node N6 corresponding to VDD-2 Vgs is provided to a gate terminal of the floating PMOS transistor MP8 and a gate terminal of the control PMOS transistor MP9.

The first output transistor MP12 is coupled between the power supply voltage VDD and the output terminal VOUT. A gate terminal of the first output transistor MP12 is coupled to the third node N3.

The second output transistor MN12 is coupled between the output terminal VOUT and the ground voltage VSS. A gate terminal of the second output transistor MN12 is coupled to the fourth node N4.

The first capacitor C1 is coupled between the third node N3 and the output terminal VOUT. The second capacitor C2 is coupled between the fourth node N4 and the output terminal VOUT.

The output circuit 60 amplifies a difference between input signals in response to voltage levels of the third node N3 and the fourth node N4 and outputs the amplified signal. Bias currents are determined by bias voltages provided to gate terminals of the transistors MP12 and MN12, and an operational amplifier formed as in FIG. 2 may perform class AB rail-to-rail operation.

FIG. 3 is a circuit diagram illustrating a rail-to-rail class AB amplifier according to an exemplary embodiment of the present invention.

Referring to FIG. 3, the rail-to-rail class AB amplifier may include the input circuit 10, the first current adder circuit 20, the second current adder circuit 30, the floating current source 40, the control circuit 50, and the output circuit 60. Hereinafter, only the first current adder circuit 20, the second current adder circuit 30, and operation of the rail-to-rail class AB amplifier will be described in detail, because the other elements are substantially the same as shown in FIG. 2.

The first current adder circuit 20 may include a first boosting amplifier 25, a third current source I3, a first cascode PMOS transistor MP4, a second PMOS transistor MP6, a first PMOS transistor MP3, a second PMOS transistor MP5, and a third PMOS transistor MP7.

The first boosting amplifier 25 may include a first boosting transistor 251, a second boosting transistor 252, a third boosting transistor 253, a fourth boosting transistor 254, and a fifth boosting transistor 255. The first boosting transistor 251, the second boosting transistor 252, and the third boosting transistor 253 may comprise PMOS transistors. The fourth boosting transistor 254 and the fifth boosting transistor 255 may comprise NMOS transistors.

A source terminal of the first boosting transistor 251 is coupled to a power supply voltage VDD. A gate terminal of the first boosting transistor 251 is coupled to the first node N1 and with gate terminals of the first and the second PMOS transistor MP3, MP5.

A source terminal of the second boosting transistor 252 is coupled to a drain terminal of the first boosting transistor 251. A gate terminal of the second boosting transistor 252 receives a first bias voltage VB1.

A source terminal of the third boosting transistor 253 is coupled to the drain terminal of the first boosting transistor 251. A gate terminal of the third boosting transistor 253 is coupled to a gate terminal of the third PMOS transistor MP7. A drain terminal of the third transistor 253 is coupled to a seventh node N7.

The fourth boosting transistor 254 is diode-connected. A drain terminal of the fourth boosting transistor 254 is coupled to a drain terminal of the second boosting transistor 252. A source terminal of the fourth boosting transistor 254 is coupled to the ground voltage VSS.

A drain terminal of the fifth boosting transistor 255 is coupled to the seventh node N7. A gate terminal of the fifth boosting transistor 255 is coupled to the gate terminal of the fourth boosting transistor 254. A source terminal of the fifth boosting transistor 255 is coupled to the ground voltage VSS.

The gate terminal of the second boosting transistor 252 may correspond to a plus input terminal of the first boosting amplifier 25. The gate terminal of the third boosting transistor 253 may correspond to a minus input terminal of the first boosting amplifier 25. The seventh node N7 may correspond to an output terminal of the first boosting amplifier 25.

The first boosting transistor 251 may provide a tail current of the first boosting amplifier 25, and may operate as a current source. The total gain may be adjustable by controlling a size of the first boosting transistor 251.

An output signal of the first boosting amplifier 25 may be provided to the second cascode PMOS transistor MPG through the seventh node N7 in response to levels of the plus input terminal and the minus input terminal.

The output signal of the first boosting amplifier 25 may increase an output impedance by being connected to the gate terminal of the second cascode PMOS transistor MP6.

The third PMOS transistor MP7 may be diode-connected and may be operated as a level shifter. The third current source I3 adjusts a drain current of the third PMOS transistor MP7 for operating the first boosting amplifier 25.

The second current adder circuit 30 may include a second boosting amplifier 35, a fourth current source I4, a first cascode NMOS transistor MN4, a second NMOS transistor MN6, a first NMOS transistor MN3, a second NMOS transistor MN5, and a third NMOS transistor MN7.

The second current adder circuit 30 may include a second boosting amplifier 35, a fourth current source I4, a first cascode NMOS transistor MN4, a second NMOS transistor MN6, a first NMOS transistor MN3, a second NMOS transistor MN5, and a third NMOS transistor MN7.

The second boosting amplifier 35 may include a sixth boosting transistor 351, a seventh boosting transistor 352, a eighth boosting transistor 353, a ninth boosting transistor 354, and a tenth boosting transistor 355. The sixth boosting transistor 351, the seventh boosting transistor 352, and the eighth boosting transistor 353 may comprise NMOS transistors. The ninth boosting transistor 354 and the tenth boosting transistor 355 may comprise PMOS transistors.

A source terminal of the sixth boosting transistor 351 is coupled to the ground voltage VSS. A gate terminal of the sixth boosting transistor 351 is coupled to the second node N2 with gate terminals of the first and the second NMOS transistor MN3, MN5.

A source terminal of the seventh boosting transistor 352 is coupled to a drain terminal of the sixth boosting transistor 351. A gate terminal of the seventh boosting transistor 352 receives a second bias voltage VB2.

A source terminal of the eighth boosting transistor 353 is coupled to the drain terminal of the sixth boosting transistor 351. A gate terminal of the eighth boosting transistor 353 is coupled to a gate terminal of the third NMOS transistor MN7. A drain terminal of the eighth boosting transistor 353 is coupled to a eighth node N8.

The ninth boosting transistor 354 is diode-connected. A drain terminal of the ninth boosting transistor 354 is coupled to a drain terminal of the seventh boosting transistor 352. A source terminal of the ninth boosting transistor 354 is coupled to the power supply voltage VDD.

A drain terminal of the tenth boosting transistor 355 is coupled to the eighth node N8. A gate terminal of the tenth boosting transistor 355 is coupled to the gate terminal of the ninth boosting transistor 354. A source terminal of the tenth boosting transistor 355 is coupled to the power supply voltage VDD.

The gate terminal of the seventh boosting transistor 352 may correspond to a plus input terminal of the second boosting amplifier 35. The gate terminal of the eighth boosting transistor 353 may correspond to a minus input terminal of the second boosting amplifier 35. The eighth node N8 may correspond to an output terminal of the second boosting amplifier 35.

The sixth boosting transistor 351 may provide a tail current of the second boosting amplifier 35, and may operate as a current source. The total gain may be adjustable by controlling a size of the sixth boosting transistor 351.

An output signal of the second boosting amplifier 35 may be provided to the second cascode NMOS transistor MN6 through the eighth node N8 in response to levels of the plus input terminal and the minus input terminal.

The output signal of the second boosting amplifier 35 may increase the output impedance by being provided to the gate terminal of the second cascode NMOS transistor MN6.

The third NMOS transistor MN7 may be diode-connected and may be operated as a level shifter. The fourth current source I4 adjusts a drain current of the third NMOS transistor MN7 for operating the second boosting amplifier 35.

A floating PMOS transistor MP8 included in the floating current source 40 receives a voltage of the sixth node N6 corresponding to VDD-2 Vgs through a gate terminal and controls a drain current. A floating NMOS transistor MN8 included in the floating current source 40 receives a voltage of the fifth node N5 corresponding to 2 Vgs through a gate terminal and controls a drain current. Thus, a total bias current may be controlled by the floating PMOS transistor MP8 and floating NMOS transistor MN8.

A control PMOS transistor MP9 included in the control circuit 50 receives a voltage of the sixth node N6 corresponding to VDD-2 Vgs through a gate terminal and controls a drain current. A control NMOS transistor MN8 included in the control circuit 50 receives a voltage of the fifth node N5 corresponding to 2 Vgs through a gate terminal and controls a drain current. Thus, the control circuit 50 enables the amplifier to operate as a rail-to-rail class AB amplifier by controlling voltages of the third node N3 and the fourth node N4 coupled to the output circuit 60.

The fourth PMOS transistor MP10, the fifth PMOS transistor MP11 and the control PMOS transistor MP9 form a first trans-linear loop. The fourth NMOS transistor MN10, the fifth NMOS transistor MN11 and the control NMOS transistor MN9 form a second trans-linear loop. Thus, a class AB output of the rail-to-rail class AB amplifier may be enabled by those two trans-linear loops.

The control PMOS transistor MP9 and the control NMOS transistor MN9 of the control circuit 50 may provide constant voltages to the first output transistor MP12 and the second output transistor MN12 by controlling voltages of the third node N3 and the fourth node N4.

The first capacitor C1 and the second capacitor C2 may be used as compensation capacitors.

As described abode, the rail-to-rail class AB amplifier according to an exemplary embodiment of the present invention may process high swing signals and perform class AB control by using input/output rail-to-rail structure and trans-linear loops.

Additionally, the rail-to-rail class AB amplifier according to an exemplary embodiment of the present invention may increase the output impedance by using a gain boosting amplifier. A total gain may be controlled easily by additional current sources.

While the exemplary embodiments of the present invention and their advantages have been described in detail, it should be understood that various changes, substitutions and alterations may be made herein without departing from the scope of the invention.

What is claimed is:

1. A rail-to-rail class AB amplifier comprising:
an input circuit for converting a voltage difference between a first input signal and a second input signal into respective currents, the input circuit including a first input PMOS transistor, a second input PMOS transistor, a first input NMOS transistor, and a second input NMOS transistor, each pair of the first input PMOS transistor and the second input PMOS transistor, and the first input NMOS transistor and the second input NMOS transistor being configured as a folded cascode circuit;
to a first current adder circuit including a first cascode PMOS transistor, a second cascode PMOS transistor, a first level shifter coupled to a source terminal of the second cascode PMOS transistor, and a first boosting amplifier the first boosting amplifier receiving a first bias voltage and an output of the first level shifter, the first boosting amplifier outputting a boosted output signal to a gate terminal of the second cascode PMOS transistor, the first cascode PMOS transistor having a source terminal coupled to a drain terminal of the first input NMOS transistor, the second cascode PMOS transistor having a source terminal coupled to a drain terminal of the second input NMOS transistor, the first current adder circuit adding a drain current of the first input NMOS transistor and a drain current of the second input NMOS transistor, the first current adder circuit outputting the added current to a drain terminal of the second cascode PMOS transistor;
a second current adder circuit including a first cascode NMOS transistor, a second cascode NMOS transistor, a second level shifter coupled to a source terminal of the second cascode NMOS transistor, and a second boosting amplifier, the second boosting amplifier receiving a second bias voltage and an output of the second level shifter, the second boosting amplifier outputting a boosted output signal to a gate terminal of the second cascode NMOS transistor, the first cascade NMOS transistor having a source terminal coupled to a drain terminal of the first input PMOS transistor, the second cascode NMOS transistor having a source terminal coupled to a drain terminal of the second input PMOS transistor, the second current adder circuit adding a drain current of the first input PMOS transistor and a drain current of the second input PMOS transistor, the second current adder circuit outputting the added current to a drain terminal of the second cascade NMOS transistor;
a floating current source coupled between a drain terminal of the first cascade PMOS transistor and a drain of the first cascade NMOS transistor, the floating current source controlling a respective bias current of the first current adder circuit and the second current adder circuit;
a control circuit coupled between the drain terminal of the second cascade PMOS transistor and a drain of the second cascade NMOS transistor, the control circuit controlling a voltage level of the drain terminal of the second cascode PMOS transistor and a voltage level of the second cascode NMOS transistor; and
an output circuit coupled to the drain terminal of the second cascode PMOS transistor and the drain terminal of the second NMOS transistor and producing an output of the amplifier.

2. The rail-to-rail class AB amplifier of claim 1, wherein the input circuit further comprises:
a first current source coupled to a power supply voltage, the first current source providing a current to the first input NMOS transistor and the second input NMOS transistor; and
a second current source coupled to a ground voltage, the second current source providing a current to the first input PMOS transistor and the second input PMOS transistor.

3. The rail-to-rail class AB amplifier of claim 1, wherein the first current adder circuit further comprises:
a first PMOS transistor having a source terminal coupled to a power supply voltage, a gate terminal coupled to the drain terminal of the first cascode PMOS transistor, and a drain terminal coupled to the drain terminal of the first input NMOS transistor; and
a second PMOS transistor having a source terminal coupled to the power supply voltage, a gate terminal coupled to the gate terminal of the first PMOS transistor, and a drain terminal coupled to the drain terminal of the second input NMOS transistor.

4. The rail-to-rail class AB amplifier of claim 3, wherein the first level shifter comprises:
a third PMOS transistor having a source terminal coupled to the source terminal of the second cascode PMOS transistor, the third PMOS transistor being diode-connected; and
a first current source coupled between a ground voltage and the third PMOS transistor, the first current source providing a current to the third PMOS transistor.

5. The rail-to-rail class AB amplifier of claim 4, wherein the first boosting amplifier comprises:
a first boosting transistor for providing a constant current, the first boosting transistor having a source terminal coupled to the power supply voltage, and a gate terminal coupled to the gate terminal of the first PMOS transistor;
a second boosting transistor having a source terminal coupled to a drain terminal of the first boosting transistor, and a gate terminal for receiving the first bias voltage;
a third boosting transistor having a source terminal coupled to the drain terminal of the first boosting transistor, and a gate terminal coupled to a drain terminal of the third PMOS transistor;
a fourth boosting transistor coupled between the second boosting transistor and the ground voltage, the fourth boosting transistor being diode-connected; and
a fifth boosting transistor having a drain terminal coupled to a drain terminal of the third boosting transistor, a gate terminal coupled to the fourth boosting transistor, and a source terminal coupled to the ground voltage.

6. The rail-to-rail class AB amplifier of claim 5, wherein each of the first, the second, and the third boosting transistors comprises a PMOS transistor, and each of the fourth and the fifth boosting transistors comprises an NMOS transistor.

7. The rail-to-rail class AB amplifier of claim 1, wherein the second current adder circuit further comprises:
a first NMOS transistor having a source terminal coupled to a ground voltage, a gate terminal coupled to the drain terminal of the first cascode NMOS transistor, and a drain terminal coupled to the drain terminal of the first input PMOS transistor; and
a second NMOS transistor having a source terminal coupled to the ground voltage, a gate terminal coupled to the gate terminal of the first NMOS transistor, and a drain terminal coupled to the drain terminal of the second input PMOS transistor.

8. The rail-to-rail class AB amplifier of claim 7, wherein the second level shifter comprises:
a third NMOS transistor having a source terminal coupled to the source terminal of the second cascode NMOS transistor, the third NMOS transistor being diode-connected; and
a second current source coupled between a power supply voltage and the third NMOS transistor, the second current source providing a current to the third NMOS transistor.

9. The rail-to-rail class AB amplifier of claim 8, wherein the second boosting amplifier comprises:
a first boosting transistor for providing a constant current, the first boosting transistor having a source terminal coupled to the ground voltage, and a gate terminal coupled to the gate terminal of the first NMOS transistor;
a second boosting transistor having a source terminal coupled to a drain terminal of the first boosting transistor, and a gate terminal for receiving the second bias voltage;
a third boosting transistor having a source terminal coupled to the drain terminal of the first boosting transistor, and a gate terminal coupled to a drain terminal of the third NMOS transistor;
a fourth boosting transistor coupled between the second boosting transistor and the power supply voltage, the fourth boosting transistor being diode-connected; and
a fifth boosting transistor having a drain terminal coupled to a drain terminal of the third boosting transistor, a gate terminal coupled to the fourth boosting transistor, and a source terminal coupled to the power supply voltage.

10. The rail-to-rail class AB amplifier of claim 9, wherein each of the first, the second, and the third boosting transistors comprises an NMOS transistor, and each of the fourth and the fifth boosting transistor corresponds to PMOS transistor.

11. The rail-to-rail class AB amplifier of claim 1, wherein the output circuit comprises:
a first output transistor having a source terminal coupled to a power supply voltage, a gate terminal coupled to the drain terminal of the second cascode PMOS transistor, and a drain terminal coupled to a output terminal; and
a second output transistor having a drain terminal coupled to the output terminal, a gate terminal coupled to the drain terminal of the second cascode NMOS transistor, and a source terminal coupled to a ground voltage.

12. The rail-to-rail class AB amplifier of claim 11, wherein the first output transistor comprises a PMOS transistor and the second output transistor comprises an NMOS transistor.

13. The rail-to-rail class AB amplifier of claim 11, wherein the output circuit further comprises:
a first capacitor coupled between the drain terminal of the second cascode PMOS transistor and the output terminal; and
a second capacitor coupled between the drain terminal of the second cascode NMOS transistor and the output terminal.

14. The rail-to-rail class AB amplifier of claim 11, wherein the output circuit further comprises:
a first branch including a first current source and a first diode serially coupled to the first current source between the power supply voltage and the ground voltage; and
a second branch including a second current source and a second diode serially coupled to the second current source between the power supply voltage and the ground voltage.

15. The rail-to-rail class AB amplifier of claim 14, wherein the first diode comprises a diode-connected NMOS transistor and the second diode comprises a diode-connected PMOS transistor.

16. The rail-to-rail class AB amplifier of claim 14, wherein the floating current source comprises:
a first floating transistor coupled between the drain terminal of the first cascode PMOS transistor and the drain terminal of the first cascode NMOS transistor, the first floating transistor having a gate terminal for receiving a voltage of a coupling node of the first current source and the first diode; and
a second floating transistor coupled between the drain terminal of the first cascode PMOS transistor and the drain terminal of the first cascode NMOS transistor, the second floating transistor having a gate terminal for receiving a voltage of a coupling node between the second current source and the second diode.

17. The rail-to-rail class AB amplifier of claim 16, wherein the first floating transistor comprises a PMOS transistor and the second floating transistor comprises an NMOS transistor.

18. The rail-to-rail class AB amplifier of claim 14, wherein the control circuit comprises:
a first control transistor coupled between the drain terminal of the second cascode PMOS transistor and the drain terminal of the second cascode NMOS transistor, the first control transistor having a gate terminal for receiving a voltage of a coupling node between the first current source and the first diode; and
a second control transistor coupled between the drain terminal of the second cascode PMOS transistor and the drain terminal of the second cascode NMOS transistor, the second control transistor having a gate terminal for receiving a voltage of a coupling node between the second current source and the second diode.

19. The rail-to-rail class AB amplifier of claim 18, wherein the first control transistor comprises a PMOS transistor and the second control transistor comprises an NMOS transistor.
